(19) United States
(12) Patent Application Publication
(10) Pub. No.: US 2026/0282721 A1
(43) Pub. Date: Sep. 17, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: Su Bin JUNG, Yongin-si (KR)

(21) Appl. No.: 19/389,273

(22) Filed: Nov. 14, 2025

(30) Foreign Application Priority Data
Mar. 11, 2025 (KR) 10-2025-0031189

(51) Int. Cl. H10K 59/80; H10K 59/131; H10K 59/50

(52) U.S. Cl. CPC H10K 59/879; H10K 59/131; H10K 59/50; H10K 59/8793

(57) ABSTRACT

A display device includes a first pixel group including a first pixel, a second pixel, a third pixel and a fourth pixel in which a plurality of emission areas are defined. A second pixel group includes a fifth pixel and a sixth pixel in which a plurality of emission areas are defined. An optical lens unit includes a first lens and a second lens. The second pixel group and the optical lens unit are disposed on the first pixel group. The fifth pixel overlaps the first pixel in a thickness direction of the optical lens unit. The first lens overlaps the second pixel in the thickness direction.

### CROSS-REFERENCE TO RELATED APPLICATIONS

This application claims priority under 36 U.S.C. §119 to Korean Patent Application No. 10-2025-0031189, filed on March 11, 2025, in the Korean Intellectual Property Office, the disclosure of which is herein incorporated by reference in its entirety.

### TECHNICAL FIELD

The present disclosure relates to displays and, more specifically, to a display device and an electronic device including the same.

### DISCUSSION OF THE RELATED ART

With the development of communications technology and media, display devices are being used to display images in various places and environments. In particular, various types of display devices, such as liquid crystal displays (LCDs) and organic light emitting diode (OLED) displays, are being widely used.

Recently, a stereoscopic image display device, which divides an image of the display device and displays the divided image in a space in front of the display device by using a lens array, has been developed. The stereoscopic image display device includes a binocular parallax type which displays a left-eye image and a right-eye image separately to provide a three-dimensional (3D) effect due to binocular parallax and a light field type which converges light emitted from each lens of the lens array onto a view area where a viewer observes the display device.

### SUMMARY

A display device includes a first pixel group comprising a first pixel, a second pixel, a third pixel and a fourth pixel in which a plurality of emission areas are defined. A second pixel group includes a fifth pixel and a sixth pixel in which a plurality of emission areas are defined. An optical lens unit includes a first lens and a second lens. The second pixel group and the optical lens unit are disposed on the first pixel group. The fifth pixel overlaps the first pixel in a thickness direction of the optical lens unit. The first lens overlaps the second pixel in the thickness direction.

The first pixel, the second pixel, the third pixel and the fourth pixel may be sequentially arranged along a first direction, and the fifth pixel, the first lens, the sixth pixel and the second lens may be sequentially arranged along the first direction.

The sixth pixel may overlap the third pixel in the thickness direction, and the second lens may overlap the fourth pixel in the thickness direction.

The optical lens unit may be disposed on a first base substrate, and the second pixel group may be disposed on a transparent substrate.

The optical lens unit may be disposed between the first base substrate and a second base substrate on the first base substrate.

The display device may further include a filler layer disposed between the first base substrate and the second base substrate.

The first base substrate may include a same material as the transparent substrate.

Transmittance of light of wiring for driving the second pixel group may be greater than transmittance of light of wiring for driving the first pixel group.

The first pixel group may be configured to emit light when a three-dimensional (3D) image is realized, and the second pixel group may be configured to emit light when a two-dimensional (2D) image is realized.

The display device may further include a polarization control unit disposed between the first pixel group and the optical lens unit.

The polarization control unit may include a third base substrate, a fourth base substrate disposed on the third base substrate, and a driving liquid crystal disposed between the third base substrate and the fourth base substrate.

The first pixel group may be configured to emit light when a 2D image and a 3D image are realized, and the second pixel group may be configured to emit light when a 2D image is realized.

The polarization control unit may further include a first driving electrode disposed between the driving liquid crystal and the fourth base substrate and a second driving electrode disposed between the driving liquid crystal and the third base substrate.

The display device may further include a fourth driving electrode and a third driving electrode disposed on the fourth driving electrode. The optical lens unit may be disposed located between the fourth driving electrode and the third driving electrode.

The first pixel group may be configured to emit light when a 2D image and a 3D image are realized, and the second pixel group may be configured to emit light when a 2D image is realized.

A processor is configured to provide an image signal. A display module is configured to receiving the image signal from the processor and displaying an image therefrom. A power module is configured to supply power to the display module. The display module includes a first pixel group including a first pixel, a second pixel, a third pixel and a fourth pixel in which a plurality of emission areas are defined. A second pixel group includes a fifth pixel and a sixth pixel in which a plurality of emission areas are defined. An optical lens unit includes a first lens and a second lens. The second pixel group and the optical lens unit are disposed on the first pixel group. The fifth pixel overlaps the first pixel in a thickness direction of the optical lens unit. The first lens overlaps the second pixel in the thickness direction.

The optical lens unit may be disposed on a first base substrate, and the second pixel group may be disposed on a transparent substrate.

Transmittance of light of wiring for driving the second pixel group may be greater than transmittance of light of wiring for driving the first pixel group.

The first pixel group may be configured to emit light when a three-dimensional (3D) image is realized, and the second pixel group may be configured to emit light when a two-dimensional (2D) image is realized.

The display device may further include a polarization control unit disposed between the first pixel group and the optical lens unit.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to an embodiment of the present specification;

FIG. 2 is a perspective view of the display device according to FIG. 1;

FIG. 3 is a cross-sectional view of a portion of a display device including emission areas;

FIG. 4 is a cross-sectional view of a non-switchable light field display;

FIG. 5 is a cross-sectional view of a first type of light field display in which a two-dimensional (2D) image is realized;

FIG. 6 is a cross-sectional view of a first type of light field display in which a three-dimensional (3D) image is realized;

FIG. 7 is a cross-sectional view of a second type of light field display in which a 2D image is realized;

FIG. 8 is a cross-sectional view of a second type of light field display in which a 3D image is realized;

FIG. 9 is a cross-sectional view of a display device according to a first embodiment of the present specification;

FIG. 10 is a cross-sectional view illustrating, in detail, emission areas realized from a second pixel group according to embodiments of the present specification;

FIG. 11 is a first modification of FIG. 9;

FIG. 12 is a second modification of FIG. 9;

FIG. 13 is a cross-sectional view of the display device according to the first embodiment in which a 2D image is realized;

FIG. 14 is a cross-sectional view of the display device according to the first embodiment in which a 3D image is realized;

FIG. 15 is a cross-sectional view of a display device according to a second embodiment of the present specification;

FIG. 16 is a cross-sectional view of a display device according to a third embodiment of the present specification;

FIG. 17 is a cross-sectional view of a display device according to a fourth embodiment of the present specification;

FIG. 18 is a block diagram of an electronic device according to an embodiment of the present specification; and

FIG. 19 is a schematic diagram of electronic devices according to various embodiments of the present specification.

### DETAILED DESCRIPTION

Aspects and features of the embodiments disclosed herein, and methods of achieving them, will become apparent upon reference to the embodiments described in detail with accompanying drawings. However, the invention according to the present disclosure is not necessarily limited to the embodiments disclosed herein, but will be embodied in many different forms, and these embodiments are provided merely to make the disclosure complete and to fully inform one of ordinary skill in the art to which the invention according to the present disclosure belongs

References to an element or layer as being “on” another element or layer include both cases in which another layer or element is directly on top of or interposed between other elements. Throughout this specification, like reference numerals may refer to like components. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although first, second, and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and to the extent that an element is not described in detail with respect to this figure, it may be understood that the element is at least similar to a corresponding element that has been described elsewhere within the present disclosure.

Embodiments of the present disclosure relate to a display device capable of selectively displaying two-dimensional (2D) or three-dimensional (3D) images with improved resolution and image quality. The device may include two vertically stacked pixel groups and an optical lens unit. The first pixel group, positioned at the base, may include multiple pixels arranged in sequence, while a second pixel group, made with a transparent substrate and high-transmittance wiring, may be positioned above it. An optical lens unit including multiple lenses may also be placed in alignment with the second pixel group. This layered arrangement may allow certain pixels from each group to overlap in the thickness direction, increasing the number of pixels contributing to a single lens’s output and thereby enhancing 3D image resolution.

In operation, the system may use the first pixel group for 3D image generation, where light from the pixels is refracted by the lenses to create distinct left-eye and right-eye views for the viewer, or use the second pixel group for 2D display without the need for additional driving electrodes. Embodiments may also support configurations for non-switchable displays, where light is always refracted, as well as switchable designs that can control whether light is refracted by altering the polarization of emitted light. This may be achieved through the use of a polarization control unit or voltage-driven birefringent lenses, enabling the display to switch between 2D and 3D modes without significant resolution loss in either mode.

By stacking pixel groups and integrating the optical lens unit into the same vertical space, embodiments may overcome limitations in lens size and placement that typically restrict resolution in 3D displays. The overlapping arrangement maximizes pixel utilization for each lens, which enhances brightness and detail in 3D mode, while still allowing for high-resolution 2D output when needed. This structure may be used to simplify manufacturing by enabling co-formation of the second pixel group and lens unit on the same substrate and provides a flexible architecture for a wide range of electronic devices such as smartphones, tablets, TVs, and head-mounted displays.

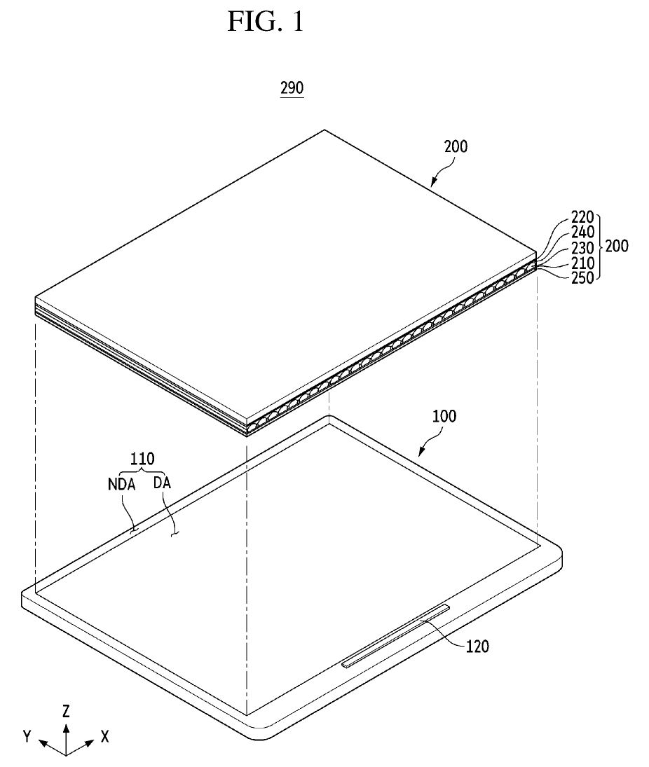

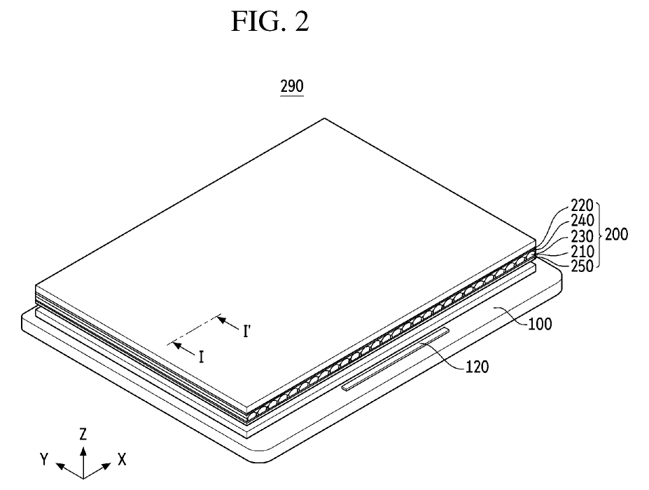

FIG. 1 is an exploded perspective view of a display device 290 according to an embodiment of the present specification. FIG. 2 is a perspective view of the display device 290 according to FIG. 1.

The display device 290 may be implemented as a flat panel display device such as a liquid crystal display (LCD), a field emission display (FED), a plasma display panel (PDP), or an organic light emitting display (OLED).

The display device 290 may be a stereoscopic image display device, for example, a three-dimensional (3D) image display device, which includes a display module 100 and an optical assembly 200. To display a 3D image, the stereoscopic image display device may display a left-eye image and a right-eye image separately in front of the display device to provide a 3D effect due to binocular parallax. Furthermore, the stereoscopic image display device may provide a plurality of viewing angle images separately in front of the display device to show different images at different viewing angles.

The display device 290, according to the embodiment, may be a light field display in which the optical assembly 200 is placed in front of the display module 100, so that different image information is shown to both eyes of a viewer. The light field display may generate a light field and create a 3D stereoscopic image by using the display module 100 which displays a two-dimensional (2D) image and the optical assembly 200 which converts the 2D image into a 3D image and displays the 3D image. As will be described later, in the light field display, image display light generated by each pixel of the display module 100 is made to form a light field in a specific direction (e.g., at a specific viewing angle and/or a specific point in time) by a stereoscopic lens, a pinhole, or a barrier included in the optical assembly 200. Accordingly, 3D stereoscopic image information corresponding to the specific direction may be provided to a viewer.

The display module 100 may include a display panel 110 and a display driver 120.

The display panel 110 may include a display area DA and a non-display area NDA. The display area DA may include data lines, scan lines, voltage supply lines, and a plurality of pixels connected to corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction).

Each pixel (or unit pixel) formed and arranged in the display panel 110 includes a minimum number of subpixels that can display white. For example, each pixel may include three subpixels that display red light, green light, and blue light, respectively. Each of the subpixels, which are arranged alternately, may be connected to at least one scan line, a data line, and a power supply line. Each of the subpixels may include thin-film transistors, which include a driving transistor and at least one switching transistor, a light emitting element, and a capacitor. Each of the pixels may receive a data voltage of a data line when a scan signal is transmitted from a scan line and may emit light by supplying a driving current to a light emitting element according to the data voltage applied to a gate electrode.

In the present specification, the pixels (e.g., the unit pixels) of the display panel 110 display a 2D multi-view image according to the image data supply order of the display driver 120. The multi-view image includes n view images (where n is an integer of 2 or more). Here, the n view images are images generated by capturing images of a specific object (or content) using n cameras spaced apart from each other by a distance between both eyes of an ordinary person.

For example, the n view images may include first data generated by collecting specific content at a first viewing angle, second data generated by collecting the specific content at a second viewing angle, …, n^{th} data generated by collecting the specific content at an n^{th} viewing angle. A plurality of data (the first data through the n^{th} data) generated by photographing the specific content may be digital data.

The display panel 110 may display a multi-view image in units of n pixels during an image display period. For example, the display panel 110 may display a multi-view image in units of two pixels. For example, two pixels of the display panel 110 may display a multi-view image including two view images. In particular, the display panel 110 may display a multi-view image in units of a time-division frame (or subframe) period according to the time-division driving of the display driver 120. In this case, a multi-view image may be displayed in units of two pixels for each time-division frame period. The time-division frame period is a period in which one frame period is divided into 1/2 or 1/3 frame periods.

The non-display area NDA may surround the display area DA at edges of the display panel 110. The non-display area NDA may include a scan driver which transmits scan signals to scan lines and pads which are connected to the display driver 120. For example, the display driver 120 may be located on a side of the non-display area NDA, and the pads may be located on an edge of the non-display area NDA where the display driver 120 is located.

The display driver 120 may output control signals and image data voltages for driving the display panel 110 in units of at least one frame or in units of at least one time-division frame (or subframe). For example, the display driver 120 may supply image data voltages to data lines in units of at least one time-division frame (or subframe). The display driver 120 may supply a power supply voltage to a power supply line and may supply scan control signals to the scan driver. The image data voltages may include a plurality of data voltages which are supplied to a plurality of pixels (or subpixels) connected to a plurality of data lines.

The optical assembly 200 includes an optical lens unit 230 (e.g., refractive anisotropic lenses) which is formed between first and second base substrates 210 and 220, a polarization control unit 250 which is stacked and overlapped with the optical lens unit 230, and a filler layer 240 which fills a space between the optical lens unit 230 and the second base substrate 220.

The display driver 120 may be formed as an integrated circuit (IC) and placed in the non-display area NDA of the display panel 110 using a chip on glass (COG) method, a chip on plastic (COP) method, or an ultrasonic bonding method. In an example, the display driver 120 may be mounted on a circuit board and connected to the pads of the display panel 110.

The optical assembly 200 may be placed in front of the display panel 110 or the display module 100. The optical assembly 200 may be attached to a surface of the display panel 110 or the display area DA through an adhesive. The optical assembly 200 may be bonded to the front of the display module 100 by a panel bonding device.

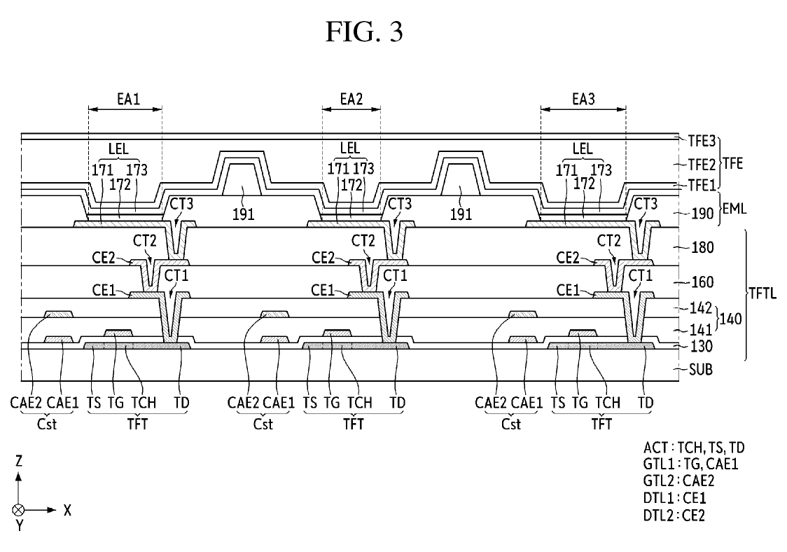

FIG. 3 is a cross-sectional view of a portion of a display device including emission areas.

Referring to FIG. 3, a display panel 110 may include a substrate SUB, a thin-film transistor layer TFTL, a light emitting element layer EML, and an encapsulation layer TFE.

The thin-film transistor layer TFTL may include an active layer ACT, a first gate metal layer GTL1, a second gate metal layer GTL2, a first data metal layer DTL1, and a second data metal layer DTL2. In addition, the thin-film transistor layer TFTL may include a buffer layer BF, a gate insulating layer 130, a first interlayer insulating film 141, a second interlayer insulating film 142, a first planarization layer 160, and a second planarization layer 180. The thin-film transistor layer TFTL may include a plurality of thin-film transistors TFT, and each of the thin-film transistors TFT may include a channel TCH, a gate electrode TG, a first electrode TS, and a second electrode TD.

The active layer ACT may be disposed on the substrate SUB. The active layer ACT may include a silicon semiconductor, such as polycrystalline silicon, monocrystalline silicon or low-temperature polycrystalline silicon, or may include an oxide semiconductor.

The active layer ACT may include the channel TCH, the first electrode TS and the second electrode TD of each of the thin-film transistors TFT. The channel TCH may be a region overlapped by the gate electrode TG of a thin-film transistor TFT in a third direction (e.g., a Z-axis direction), which is a thickness direction of the substrate SUB. The first electrode TS may be disposed on a side of the channel TCH, and the second electrode TD may be disposed on the other side of the channel TCH. The first electrode TS and the second electrode TD may be regions not overlapped by the gate electrode TG in the third direction (e.g., the Z-axis direction). The first electrode TS and the second electrode TD may be regions formed to have conductivity by doping a silicon semiconductor or an oxide semiconductor with ions.

The gate insulating layer 130 may be disposed on the active layer ACT. The gate insulating layer 130 may include an inorganic layer, for example, a silicon nitride layer, a silicon oxynitride layer, a silicon oxide layer, a titanium oxide layer, or an aluminum oxide layer.

The first gate metal layer GTL1 may be disposed on the gate insulating layer 130. The first gate metal layer GTL1 may include the gate electrode TG of each of the thin-film transistors TFT and first capacitor electrodes CAE1. The first gate metal layer GTL1 may be a single layer or a multilayer structure including any one or more of molybdenum (Mo), aluminum (Al), chromium (Cr), gold (Au), titanium (Ti), nickel (Ni), neodymium (Nd), copper (Cu), and alloys thereof.

The first interlayer insulating film 141 may be disposed on the first gate metal layer GTL1. The first interlayer insulating film 141 may include an inorganic layer, for example, a silicon nitride layer, a silicon oxynitride layer, a silicon oxide layer, a titanium oxide layer, or an aluminum oxide layer.

The second gate metal layer GTL2 may be disposed on the first interlayer insulating film 141. The second gate metal layer GTL2 may include second capacitor electrodes CAE2. The second capacitor electrodes CAE2 may overlap the first capacitor electrodes CAE1 in the third direction (e.g., the Z-axis direction). Each capacitor Cst may include a first capacitor electrode CAE1 and a second capacitor electrode CAE2. The second gate metal layer GTL2 may be a single layer or a multilayer structure including any one or more of molybdenum (Mo), aluminum (Al), chromium (Cr), gold (Au), titanium (Ti), nickel (Ni), neodymium (Nd), copper (Cu), and alloys thereof.

The second interlayer insulating film 142 may be disposed on the second gate metal layer GTL2. The second interlayer insulating film 142 may include an inorganic layer, for example, a silicon nitride layer, a silicon oxynitride layer, a silicon oxide layer, a titanium oxide layer, or an aluminum oxide layer.

The first data metal layer DTL1 including first connection electrodes CE1 may be disposed on the second interlayer insulating film 142. Each of the first connection electrodes CE1 may be connected to the first electrode TS or the second electrode TD of a thin-film transistor TFT through a first contact hole CT1 which penetrates the gate insulating layer 130, the first interlayer insulating film 141, and the second interlayer insulating film 142. The first data metal layer DTL1 may be a single layer or a multilayer structure including any one or more of molybdenum (Mo), aluminum (Al), chromium (Cr), gold (Au), titanium (Ti), nickel (Ni), neodymium (Nd), copper (Cu), and alloys thereof.

The first planarization layer 160 may be disposed on the first data metal layer DTL1 to planarize steps caused by the active layer ACT, the first gate metal layer GTL1, the second gate metal layer GTL2, and the first data metal layer DTL1. The first planarization layer 160 may include an organic layer such as acryl resin, epoxy resin, phenolic resin, polyamide resin, or polyimide resin.

The second data metal layer DTL2 may be disposed on the first planarization layer 160. The second data metal layer DTL2 may include second connection electrodes CE2. Each of the second connection electrodes CE2 may be connected to a first connection electrode CE1 through a second contact hole CT2 which penetrates the first planarization layer 160. The second data metal layer DTL2 may be a single layer or a multilayer structure including any one or more of molybdenum (Mo), aluminum (Al), chromium (Cr), gold (Au), titanium (Ti), nickel (Ni), neodymium (Nd), copper (Cu), and alloys thereof.

The second planarization layer 180 may be disposed on the second data metal layer DTL2. The second planarization layer 180 may include an organic layer such as acryl resin, epoxy resin, phenolic resin, polyamide resin, or polyimide resin.

The light emitting element layer EML may be disposed on the second planarization layer 180. The light emitting element layer EML may include a plurality of light emitting elements LEL and a pixel defining layer 190. Each of the light emitting elements LEL may be, but is not necessarily limited to, an organic light emitting diode element including a pixel electrode 171, a light emitting layer 172, and a common electrode 173.

The pixel electrode 171 may be disposed on the second planarization layer 180. The pixel electrode 171 may be connected to a second connection electrode CE2 through a third contact hole CT3 which penetrates the second planarization layer 180.

In a top emission structure in which light is emitted in a direction from the light emitting layer 172 toward the common electrode 173, the pixel electrode 171 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 190 may be disposed on the second planarization layer 180 and may cover edges of each of the pixel electrodes 171 to define a plurality of emission areas EA1, EA2 and EA3. The pixel defining layer 190 may include an organic layer such as acryl resin, epoxy resin, phenolic resin, polyamide resin, or polyimide resin.

Each of the emission areas EA1, EA2 and EA3 is an area in which the pixel electrode 171, the light emitting layer 172, and the common electrode 173 are sequentially stacked so that holes from the pixel electrode 171 and electrons from the common electrode 173 are recombined with each other in the light emitting layer 172 to emit light.

The light emitting layer 172 may be disposed on the pixel electrode 171. The light emitting layer 172 may include an organic material to emit light of a selected color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed in common in the emission areas EA1, EA2 and EA3. A capping layer may be formed on the common electrode 173.

In the top emission structure, the common electrode 173 may include a transparent conductive material (TCO) that can transmit light, such as indium tin oxide (ITO) or indium zinc oxide (IZO), or may include a semi-transmissive conductive material such as magnesium (Mg), silver (Ag) or an alloy of Mg and Ag. When the common electrode 173 includes a semi-transmissive conductive material, light output efficiency may be increased by a microcavity.

Spacers 191 may be disposed on the pixel defining layer 190. The spacers 191 may support a mask during a process of forming the light emitting layers 172. The spacers 191 may include an organic layer such as acryl resin, epoxy resin, phenolic resin, polyamide resin, or polyimide resin.

The encapsulation layer TFE may be disposed on the common electrode 173. The encapsulation layer TFE may include at least one inorganic layer to prevent oxygen or moisture from penetrating into the light emitting element layer EML. In addition, the encapsulation layer TFE may include at least one organic layer to protect the light emitting element layer EML from foreign substances such as dust. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be disposed on the common electrode 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer structure in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as acryl resin, epoxy resin, phenolic resin, polyamide resin, or polyimide resin.

As illustrated, a third emission area EA3 may be larger than a first emission area EA1, and the first emission area EA1 may be larger than a second emission area EA2. Here, the first emission area EA1 may be a red light-emitting area, the second emission area EA2 may be a green light-emitting area, and the third emission area EA3 may be a blue light-emitting area. However, embodiments of the present specification are not necessarily limited to the relative sizes of the emission areas.

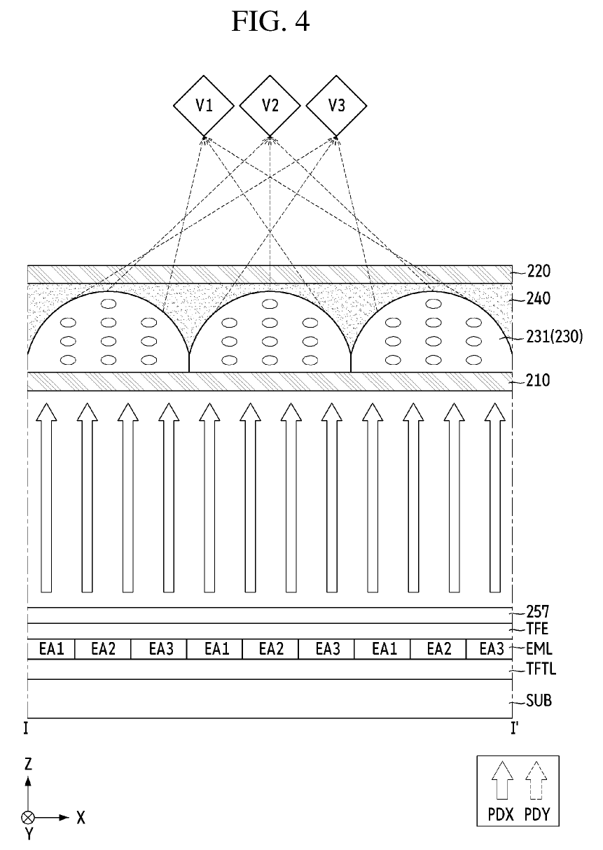

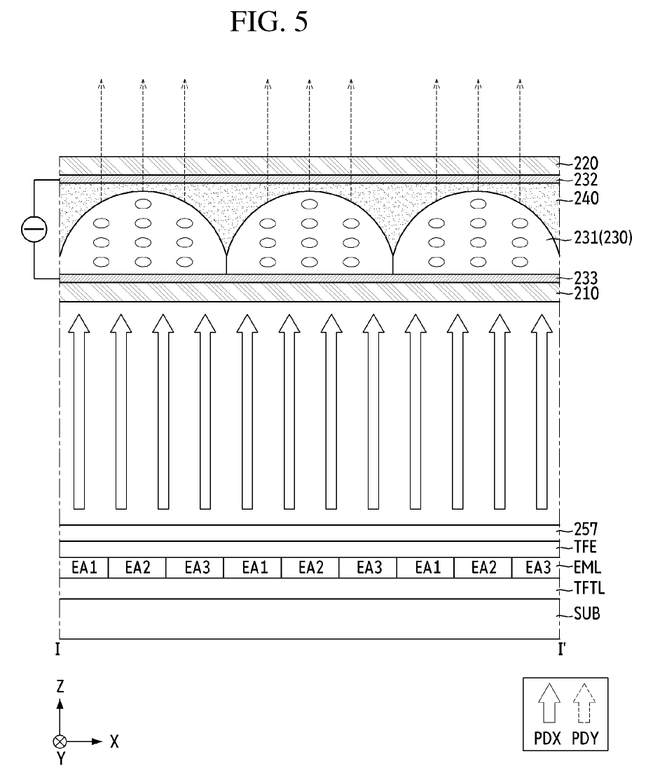

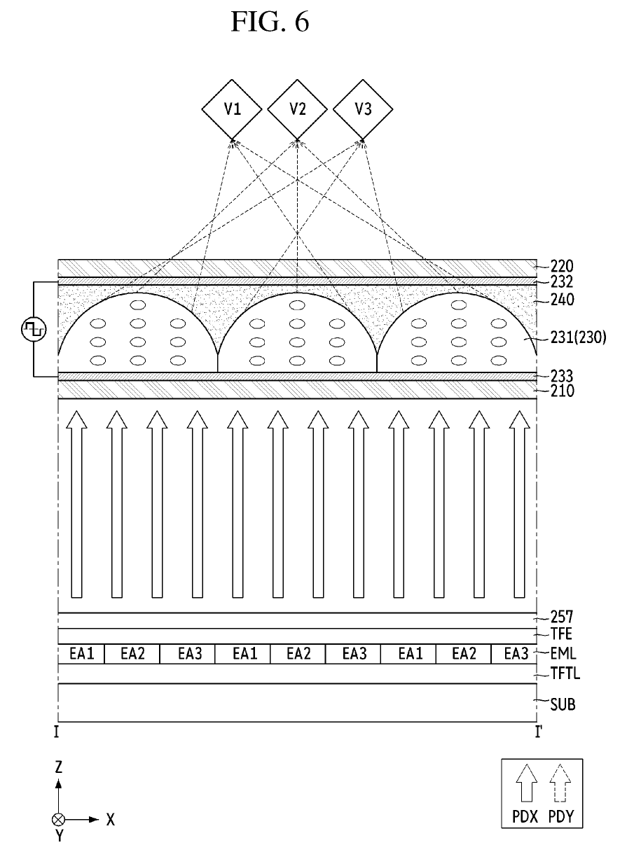

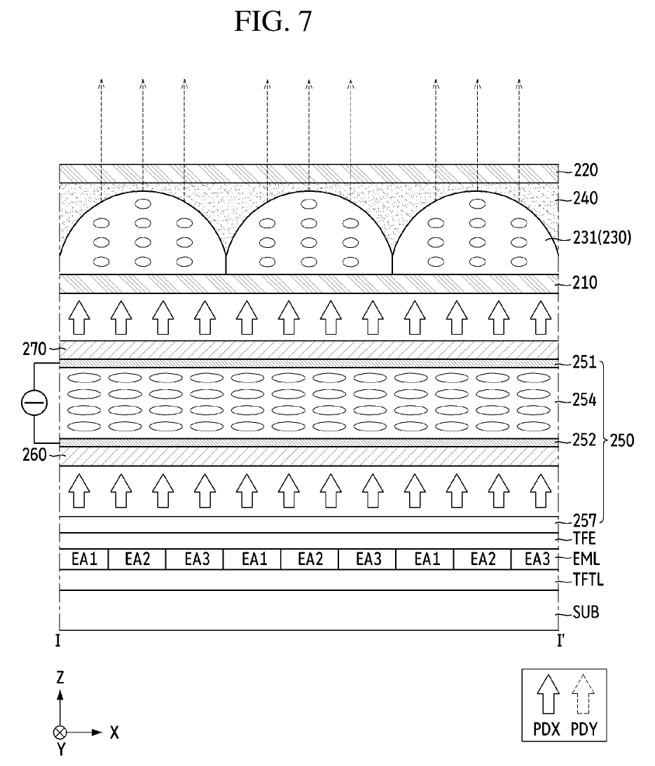

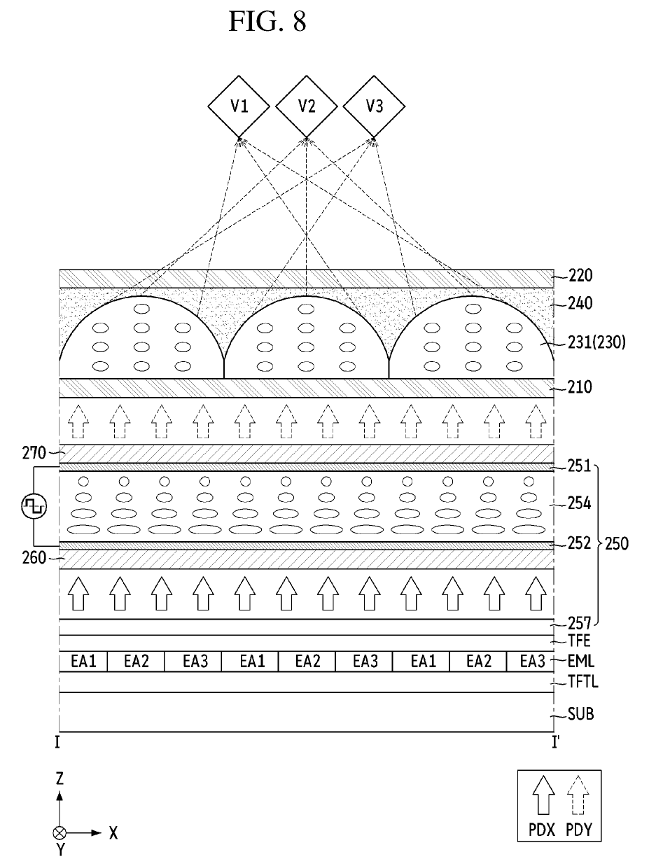

FIG. 4 is a cross-sectional view of a non-switchable light field display. FIG. 5 is a cross-sectional view of a first type of light field display in which a 2D image is realized. FIG. 6 is a cross-sectional view of a first type of light field display in which a 3D image is realized. FIG. 7 is a cross-sectional view of a second type of light field display in which a 2D image is realized. FIG. 8 is a cross-sectional view of a second type of light field display in which a 3D image is realized.

In a light field display, an optical assembly is placed in front of a display module as described above, so that different image information is shown to both eyes of a viewer. The light field display may realize a 2D image or a 3D image.

Specific content may include all things existing in the real world, such as text, pictures and objects, as well as all things realized as digital data and not existing in the real world. The specific content may be collected at a first viewing angle to produce first data. The specific content may be collected at a second viewing angle to produce second data. In addition, when the specific content is collected at an n^{th} viewing angle, n^{th} data may be produced.

A display device, according to an embodiment, may include a display panel in which a plurality of light emitting elements are arranged and an optical assembly which is disposed on the display panel. Light emitted from a light emitting element disposed in the display panel may or might not be refracted while passing through the optical assembly, depending on whether a 3D image is to be realized. For example, when a 3D image is to be realized, light emitted from a light emitting element may be refracted by the optical assembly. For example, when a 2D image is to be realized, light emitted from a light emitting element might not be refracted by the optical assembly.

However, even when a 2D image is to be realized, light emitted from a light emitting element may be refracted. In this case, the resolution of the display device may be reduced.

A viewing angle may be assigned to each of the light emitting elements by adjusting a direction in which light emitted from the light emitting elements is refracted. This may be referred to as viewing angle mapping. The pitch, tilt angle, etc. of a lens (e.g., a slanted lens) included in the optical assembly may be adjusted to control the direction of light emitted from the light emitting elements.

A specific viewing angle may be mapped to each of the light emitting elements, and light emitted from the mapped light emitting element may travel in the assigned viewing angle direction. For example, light emitted from a light emitting element to which the first viewing angle is mapped may travel in a first viewing angle direction in which a first view area is disposed, and light emitted from a light emitting element to which the second viewing angle is mapped may travel in a second viewing angle direction in which a second view area is disposed.

The first data produced by collecting specific content at the first viewing angle may be input to the light emitting element to which the first viewing angle is mapped. The second data may be input to the light emitting element to which the second viewing angle is mapped.

The first viewing angle may be disposed on a side (e.g., a left-eye side) of a midpoint between both eyes of a user. The second viewing angle may be disposed on the other side (e.g., a right-eye side) of the midpoint between both eyes of the user.

Regardless of which viewing angle is mapped, if different images are perceived by left and right eyes of a user, respectively, the user may feel that a 3D image is realized from the display device. If the same image is perceived by the left and right eyes of the user, the user may feel that a 2D image is realized from the display device. The case where the same image is perceived by the left and right eyes of the user may be when light emitted from the display panel is not refracted. However, as described above, even if light emitted from the display panel is refracted, the same image may be perceived by the left and right eyes of the user. In this case, the resolution of the display device may be reduced.

Therefore, a user may feel a 3D image from an image realized by inputting the first data to the light emitting element to which the first viewing angle is mapped and inputting the second data to the light emitting element to which the second viewing angle is mapped.

A user may feel a 2D image from an image realized by inputting the first data to both the light emitting element to which the first viewing angle is mapped and the light emitting element to which the second viewing angle is mapped. Light emitted from the light emitting element to which the first viewing angle is mapped is still refracted even when a 2D image is realized, and light emitted from the light emitting element to which the second viewing angle is mapped is also still refracted.

Alternatively, a 2D image may be realized when light emitted from a light emitting element is not refracted by the optical assembly. In this case, a user may feel a 2D image because the light emitted from the light emitting element is not refracted regardless of the viewing angle mapped to the light emitting element. The resolution of the 2D image realized thus may be relatively higher than the resolution of a 2D image realized when the same image is perceived by left and right eyes of a user even though light is refracted.

For example, a 2D image may be realized when light emitted from a light emitting element is not refracted by the optical assembly or when the same data is input to both eyes of a user even if the light is refracted. In addition, the resolution may be different in each case.

Light field displays may include a switchable display which can determine whether to realize a 2D image or a 3D image by controlling whether to refract light emitted from a display panel and a non-switchable display which always refracts light emitted from a display panel. Even in the non-switchable display in which light emitted from the display panel is always refracted, a 2D image may be realized if the same data is input regardless of the viewing angle mapped to a light emitting element as described above. When a 2D image is realized in the non-switchable display, resolution may be reduced.

The switchable display may determine whether to realize a 2D image or a 3D image by controlling a linear polarization direction of light emitted from the display panel and utilizing the refractive index anisotropy of a lens included in an optical lens unit.

For example, light emitted from the display panel may pass through a polarizer disposed on the display panel and may exit along a path in a first linear polarization direction.

In an embodiment, a minor-axis direction of a lens included in the optical lens unit may coincide with the first linear polarization direction. A major-axis direction of the lens may coincide with a second linear polarization direction.

The optical lens unit may further include a filler layer disposed on a plurality of lenses. The lenses may have birefringence characteristics. For example, a refractive index of a lens in the minor-axis direction may be equal to a refractive index of the filler layer, and a refractive index of the lens in the major-axis direction may be greater than the refractive index of the filler layer. However, embodiments of the present specification are not necessarily limited to this example.

In the above case, if no voltage is applied to the lens, the minor-axis direction of the lens may be parallel to a path in the first linear polarization direction. When light having a path in the first linear polarization direction and emitted from the display panel passes through the lens, the light may experience the refractive index in the minor-axis direction which coincides with the first linear polarization direction. Since the refractive index of the lens in the minor-axis direction is equal to the refractive index of the filler layer, the light passing through the lens may travel straight without being refracted at an interface between the lens and the filler layer. In this case, since the light is not refracted, the light perceived by both eyes of a user may be straight light, and the user may feel that a 2D image is realized. This mechanism may be applied to a first type of light field display in which a 2D image is realized (see FIG. 5).

In the above case, if a voltage is applied to the lens, the major-axis direction of the lens may be parallel to a path in the first linear polarization direction. When light having a path in the first linear polarization direction and emitted from the display panel passes through the lens, the light may experience the refractive index in the major-axis direction which coincides with the first linear polarization direction. Since the refractive index of the lens in the major-axis direction is greater than the refractive index of the filler layer, the light passing through the lens may be refracted at the interface between the lens and the filler layer. In this case, since the light is refracted, the light perceived by both eyes of a user may be refracted light, and the user may feel that a 3D image is realized. This mechanism may be applied to a first type of light field display in which a 3D image is realized (see FIG. 6).

In a second type of light field display, no voltage may be applied to the lens, and the minor-axis direction and the major-axis direction of the lens may be fixed to be parallel to the first linear polarization direction and the second linear polarization direction, respectively (see FIGS. 7 and 8). Instead, light having a path in the first linear polarization direction and emitted from the display panel may pass through driving liquid crystals disposed between driving electrodes. The light passing through the driving liquid crystals to which no voltage is applied may pass through the driving liquid crystals while maintaining the path in the first linear polarization direction (see FIG. 7). The light passing through the driving liquid crystals to which a voltage is applied may pass through the driving liquid crystals while switching from the path in the first linear polarization direction to a path in the second linear polarization direction (see FIG. 8).

Since the minor-axis direction and the major-axis direction of the lens are parallel to the first linear polarization direction and the second linear polarization direction, respectively, if the light passing through the driving liquid crystals has the path in the first linear polarization direction, the light may experience the refractive index of the lens in the minor-axis direction. If the light passing through the driving liquid crystals has the path in the second linear polarization direction, the light may experience the refractive index of the lens in the major-axis direction. The refractive index of the lens in the minor-axis direction is equal to the refractive index of the filler layer, and the refractive index of the lens in the major-axis direction is greater than the refractive index of the filler layer. Therefore, whether the light passing through the driving liquid crystals will be refracted at the interface between the lens and the filler layer may be determined by the linear polarization direction of the light passing through the driving liquid crystals.

As described above, switchable light field displays may include a first type of light field display (see FIGS. 5 and 6) and a second type of light field display (see FIGS. 7 and 8).

In the first type of light field display, the linear polarization direction of light passing through a display panel is not changed as described above. Instead, the first type of light field display may directly change the major-axis direction and the minor-axis direction of a lens having birefringence characteristics. A changed axial direction may coincide with the linear polarization direction of the light passing through the display panel, and the light may pass through an interface while experiencing a refractive index in the changed axial direction.

In the second type of light field display, the linear polarization direction of light passing through a display panel may be changed as the light passes through driving liquid crystals. Instead, the second type of light field display cannot directly change the major- and minor-axis directions of a lens having birefringence characteristics. Therefore, the linear polarization direction of the light passing through the driving liquid crystals may coincide with a fixed axial direction of the lens, and the light may pass through an interface while experiencing a refractive index in the fixed axial direction.

Referring to FIGS. 7 and 8, in the second type of light field display, the display panel may include a substrate SUB, a thin-film transistor layer TFTL, a light emitting element layer EML, and an encapsulation layer TFE.

The substrate SUB may have rigidity to support elements formed on the substrate SUB. For example, the substrate SUB may be a glass substrate or a plastic substrate such as polyethylene terephthalate (PET).

The thin-film transistor layer TFTL may be disposed on the substrate SUB. The thin-film transistor layer TFTL may control the brightness of the display device 290. The thin-film transistor layer TFTL may include transistors.

The light emitting element layer EML may be disposed on the thin-film transistor layer TFTL. The light emitting element layer EML may include first through third emission areas EA1 through EA3. The first through third emission areas EA1 through EA3 may be alternately arranged.

The encapsulation layer TFE may be disposed on the light emitting element layer EML. The encapsulation layer TFE may include at least one inorganic layer and at least one organic layer to encapsulate the light emitting element layer EML.

An optical assembly may include an optical lens unit 230 disposed between a first base substrate 210 and a second base substrate 220. The optical lens unit 230 may include a plurality of lenses 231. The optical assembly may include a filler layer 240 disposed between the first base substrate 210 and the second base substrate 220. Although the filler layer 240 is illustrated as being disposed on the optical lens unit 230, embodiments of the present specification are not necessarily limited to this case. For example, light passing through the display panel may also pass through the filler layer 240 first and then pass through the optical lens unit 230. In addition, although the lenses 231 in the optical lens unit 230 are convex in the third direction (e.g., the Z-axis direction), embodiments of the present specification are not necessarily limited to this case.

As described above, a refractive index range of a material having refractive index anisotropy in the lenses 231 and a refractive index value of the filler layer 240 are adjusted, and then whether light is to be refracted is determined based on the presence or absence of a difference in refractive index. Therefore, the vertical relationship between the optical lens unit 230 and the filler layer 240, the convex direction of the lenses 231, etc. are within a range that can be simply designed and modified by those of ordinary skill in the art according to embodiments.

The first base substrate 210, the second base substrate 220, a third base substrate 260, and a fourth base substrate 270 may include a material that can transmit light, such as glass or plastic.

A polarization control unit 250 may be formed behind the first base substrate 210 or in front of the display panel in order to switch 2D image display light of the display panel to a path PDX or PDY in the first linear polarization direction or the second linear polarization direction and output the 2D image display light along the path PDX or PDY in the first linear polarization direction or the second linear polarization direction. The polarization control unit 250 may include a first driving electrode 251, a second driving electrode 252, and driving liquid crystals 254 disposed between the first driving electrode 251 and the second driving electrode 252. The polarization control unit 250 may further include a polarizer257 disposed on the display panel.

The polarization control unit 250 may control light, which is incident along a path PDX in the first linear polarization direction through the polarizer257, to pass through the polarization control unit 250 along the path PDX in the first linear polarization direction or may switch the light to a path PDY in the second linear polarization direction and control the light to pass through the polarization control unit 250 along the path PDY in the second linear polarization direction.

The polarization control unit 250 may also switch light, which is incident along a path PDX in the first linear polarization direction through the polarizer257, to a path in an arbitrary linear polarization direction between the first linear polarization direction and the second linear polarization direction and may control the light to pass through the polarization control unit 250 along the path in the arbitrary linear polarization direction.

For example, the first linear polarization direction may be parallel to the first direction (e.g., the X-axis direction), and the second linear polarization direction may be parallel to the second direction (e.g., the Y-axis direction), but embodiments of the present specification are not necessarily limited to this example.

At least some elements (251, 252, 254) of the polarization control unit 250 may be disposed between the third base substrate 260 and the fourth base substrate 270. The other element 257 of the polarization control unit 250 may be disposed between the display panel and the third base substrate 260.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. The shape of the second driving electrode 252 may correspond to the shape of the first driving electrode 251. A voltage may be applied to the second driving electrode 252. The driving liquid crystals 254 may control the linear polarization direction of light by a difference between the voltage applied to the first driving electrode 251 and the voltage applied to the second driving electrode 252.

The polarizer 257 may be disposed between the display panel and the third base substrate 260. Light emitted from the display panel may vibrate in all directions (e.g., may be unpolarized). The polarizer 257 may transmit only light vibrating in a specific direction among the light emitted from the display panel and may block the rest. In an embodiment, the polarizer 257 may transmit only light having a path PDX in the first linear polarization direction among the light emitted from the display panel, but embodiments of the present specification are not necessarily limited to this case.

The driving liquid crystals 254 may be disposed between the first driving electrode 251 and the second driving electrode 252. The driving liquid crystals 254 may include liquid crystals which are birefringent materials. The arrangement of the driving liquid crystals 254 may vary according to the difference between the voltages applied to the first driving electrode 251 and the second driving electrode 252. The driving liquid crystals 254 may be twisted nematic (TN) liquid crystals.

Referring to FIG. 7, the difference between the voltage applied to the first driving electrode 251 and the voltage applied to the second driving electrode 252 during a 2D image display period may be less than a selected value. The driving liquid crystals 254 may maintain the linear polarization direction of incident light having a path PDX in the first linear polarization direction. The light passing through the driving liquid crystals 254 may still have the path PDX in the first linear polarization direction.

Referring to FIG. 8, the difference between the voltage applied to the first driving electrode 251 and the voltage applied to the second driving electrode 252 during a 3D image display period may be equal to or greater than the selected value. The driving liquid crystals 254 may change the linear polarization direction of incident light having a path PDX in the first linear polarization direction. The light passing through the driving liquid crystals 254 may have a path PDY in the second linear polarization direction.

Referring again to FIGS. 7 and 8, the first base substrate 210, the second base substrate 220, and the optical lens unit 230 disposed between the first base substrate 210 and the second base substrate 220 may be placed on the fourth base substrate 270. The optical lens unit 230 may be formed in the form of a lens sheet including lenses arranged side by side. The polarization control unit 250 may be stacked and overlapped with the optical lens unit 230 which is formed in the form of a lens sheet.

The optical lens unit 230 may include a plurality of lenses 231.

Light passing through the lenses 231 may experience a refractive index of the lenses 231 in the major-axis direction, a refractive index in the minor-axis direction, or countless refractive indices in directions between the major axis and the minor axis, depending on the arrangement of birefringent materials (e.g., liquid crystals or slits) included in the lenses 231. The countless refractive indices in the directions between the major axis and the minor axis of each of the lenses 231 may be smaller than the refractive index in the major-axis direction and greater than the refractive index in the minor-axis direction, but embodiments of the present specification are not necessarily limited to this case. For example, the countless refractive indices in the directions between the major axis and the minor axis of each of the lenses 231 may also be smaller than the refractive index in the minor-axis direction and greater than the refractive index in the major-axis direction.

In an embodiment, the major-axis direction of the lenses 231 may be parallel to the second direction (e.g., the Y-axis direction), and the minor-axis direction of the lenses 231 may be parallel to the first direction (e.g., the X-axis direction). In addition, the refractive index of the filler layer 240 disposed on the lenses 231 may be equal to the refractive index of the lenses 231 in the minor-axis direction and may be smaller than the refractive index of the lenses 231 in the major-axis direction, but embodiments of the present specification are not necessarily limited to this case.

Referring to FIG. 7, light passing through the driving liquid crystals 254 may have a path PDX in the first linear polarization direction, and the first linear polarization direction may be coincident with or parallel to the first direction (e.g., the X-axis direction). Therefore, the light passing through the driving liquid crystals 254 may experience the refractive index of the lenses 231 in the minor-axis direction. Since the refractive index of the lenses 231 in the minor-axis direction is equal to the refractive index of the filler layer 240, the light passing through the driving liquid crystals 254 may travel straight without being refracted at interfaces between the lenses 231 and the filler layer 240. A 2D image may be realized from the second type of light field display by the un-refracted light.

Referring to FIG. 8, light passing through the driving liquid crystals 254 may have a path PDY in the second linear polarization direction, and the second linear polarization direction may be coincident with or parallel to the second direction (e.g., the Y-axis direction). Therefore, the light passing through the driving liquid crystals 254 may experience the refractive index of the lenses 231 in the major-axis direction. Since the refractive index of the lenses 231 in the major-axis direction is greater than the refractive index of the filler layer 240, the light passing through the driving liquid crystals 254 may be refracted at the interfaces between the lenses 231 and the filler layer 240. A 3D image may be realized from the second type of light field display by the refracted light. The refracted light may travel to a first view area V1, a second view area V2, and a third view area V3 according to mapped viewing angles.

The filler layer 240 may be disposed on the lenses 231. The second base substrate 220 may be disposed on the filler layer 240.

The filler layer 240 may include a transparent material that can transmit light. For example, the filler layer 240 may include an isotropic polymer material.

As described above, the refractive index of the filler layer 240 may be equal to the refractive index of liquid crystals in the lenses 231 in the minor-axis direction. The refractive index of the filler layer 240 may be smaller than the refractive index of the liquid crystals in the lenses 231 in the major-axis direction. Accordingly, light passing through the lenses 231 may or might not be refracted at the interfaces.

Referring to FIGS. 5 and 6, in the first type of light field display, the display panel may include a substrate SUB, a thin-film transistor layer TFTL, a light emitting element layer EML, and an encapsulation layer TFE. Elements having substantially the same functions as those of the second type of light field display described above are indicated by like reference characters, and to the extent that an element is not described in detail with respect to this figure, it may be understood that the element is at least similar to a corresponding element that has been described elsewhere within the present disclosure.

A polarizer 257 may be disposed between the display panel and a first base substrate 210. Light emitted from the display panel may vibrate in all directions (e.g., may be unpolarized). The polarizer 257 may transmit only light vibrating in a specific direction among the light emitted from the display panel and may block the rest. In an embodiment, the polarizer 257 may transmit only light having a path PDX in the first linear polarization direction among the light emitted from the display panel, but embodiments of the present specification are not necessarily limited to this case.

A third driving electrode 232 may be disposed between the first base substrate 210 and a second base substrate 220, and a fourth driving electrode 233 may be disposed between the first base substrate 210 and the third driving electrode 232. An optical lens unit 230 including lenses 231 may be disposed between the third driving electrode 232 and the fourth driving electrode 233. A filler layer 240 may be disposed on the optical lens unit 230, but as described above, the vertical relationship between them is not necessarily limited to that illustrated in the drawings.

Voltages may be applied to the third driving electrode 232 and the fourth driving electrode 233, and the lenses 231 may include liquid crystals which are birefringent materials. The arrangement of the liquid crystals in the lenses 231 may vary according to a difference between the voltages applied to the third driving electrode 232 and the fourth driving electrode 233.

Referring to FIG. 5, the difference between the voltage applied to the third driving electrode 232 and the voltage applied to the fourth driving electrode 233 during a 2D image display period may be less than a selected value. Light passing through the display panel may have a path PDX in the first linear polarization direction. The first linear polarization direction may be coincident with or parallel to the minor-axis direction of the liquid crystals in the lenses 231. The light may pass through the liquid crystals while experiencing a refractive index of the liquid crystals in the minor-axis direction. Since the refractive index in the minor-axis direction is equal to a refractive index of the filler layer 240, the light might not be refracted at interfaces. A 2D image may be realized from the first type of light field display by the un-refracted light.

Referring to FIG. 6, the difference between the voltage applied to the third driving electrode 232 and the voltage applied to the fourth driving electrode 233 during a 3D image display period may be equal to or greater than the selected value. Light passing through the display panel may have a path PDX in the first linear polarization direction. The first linear polarization direction may be coincident with or parallel to the major-axis direction of the liquid crystals in the lenses 231. The light may pass through the liquid crystals while experiencing a refractive index of the liquid crystals in the major-axis direction. Since the refractive index in the major-axis direction is greater than the refractive index of the filler layer 240, the light may be refracted at the interfaces. A 3D image may be realized from the first type of light field display by the refracted light. The refracted light may travel to a first view area V1, a second view area V2, and a third view area V3 according to mapped viewing angles.

In the above description, it is assumed that the refractive index of the filler layer 240 is equal to the refractive index of the lenses 231 or the liquid crystals in the lenses 231 in the minor-axis direction and is smaller than the refractive index in the major-axis direction. In addition, it is assumed that linear polarization directions are specified in the first and second types of light field displays. In addition, it is assumed that in the first type of light field display, a 2D image is realized when no voltage is applied to the third driving electrode 232 and the fourth driving electrode 233, and a 3D image is realized when voltages are applied. In addition, it is assumed that in the second type of light field display, a 2D image is realized when no voltage is applied to the first driving electrode 251 and the second driving electrode 252, and a 3D image is realized when voltages are applied.

However, this is an example used for ease and consistency of description, and variables, such as a refractive index range based on the birefringence characteristics of liquid crystals, the refractive index value of the filler layer, and the linear polarization direction of light passing through an individual element, can be freely and simply designed and modified within the scope of practice of those of ordinary skill in the art.

However, in the first type of light field display, the major-axis direction and the minor-axis direction of the liquid crystals in the lenses 231 may be directly changed. In the second type of light field display, the linear polarization direction of light passing through the display panel may be directly changed.

Referring to FIG. 4, in the non-switchable display, the linear polarization direction of light, the orientation direction of liquid crystals, etc. do not change, and a 3D image may always be realized. As described above, even in the non-switchable display, a user may feel a 2D image from an image realized by inputting the first data to both a light emitting element to which the first viewing angle is mapped and a light emitting element to which the second viewing angle is mapped. Light emitted from the light emitting element to which the first viewing angle is mapped is still refracted even when a 2D image is realized, and light emitted from the light emitting element to which the second viewing angle is mapped is also still refracted. In this case, however, since the viewing angles are separate, light input to either eye will fall below half of the overall resolution of the display panel. Therefore, the problem of resolution reduction may occur. In general, a 3D image is realized in the non-switchable display because light is always refracted.

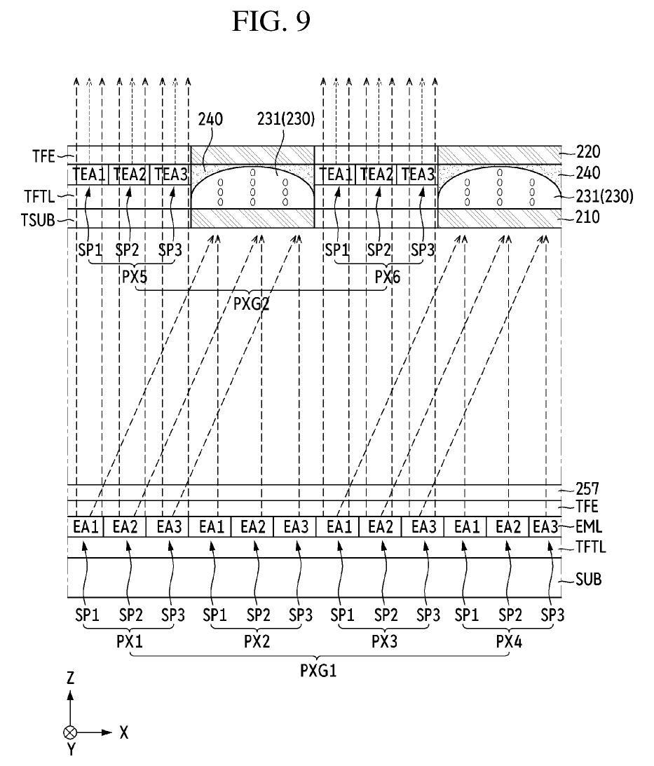

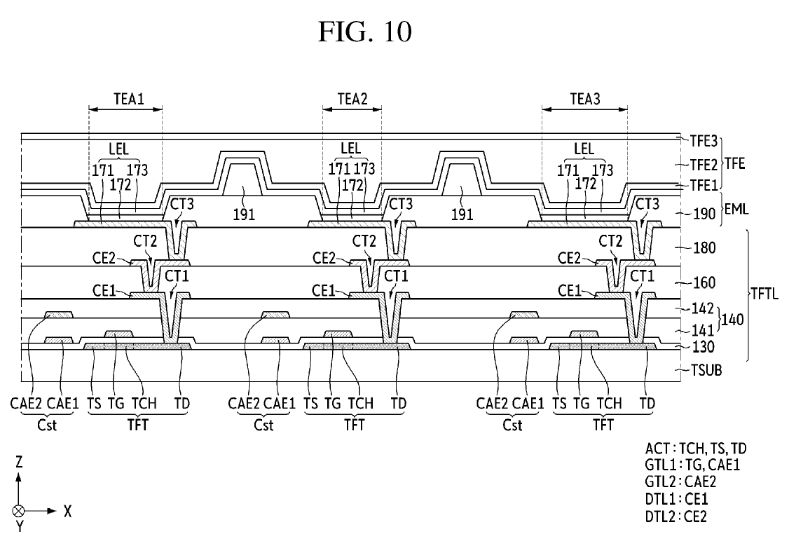

FIG. 9 is a cross-sectional view of a display device according to a first embodiment of the present specification. FIG. 10 is a cross-sectional view illustrating, in detail, emission areas realized from a second pixel group according to embodiments of the present specification. Elements having substantially the same functions as those indicated by the reference characters described above are indicated by like reference characters, and to the extent that an element is not described in detail with respect to this figure, it may be understood that the element is at least similar to a corresponding element that has been described elsewhere within the present disclosure.

Referring to FIGS. 9 and 10, the display device according to the first embodiment includes a first pixel group PXG1, a second pixel group PXG2, and an optical lens unit 230. The second pixel group PXG2 and the optical lens unit 230 may be disposed on the first pixel group PXG1.

The first pixel group PXG1 may include a plurality of pixels. The first pixel group PXG1 may include a first pixel PX1, a second pixel PX2, a third pixel PX3, and a fourth pixel PX4 sequentially arranged along the first direction (e.g., the X-axis direction). Each pixel may include a plurality of subpixels. The subpixels may include a first subpixel SP1 which realizes a first emission area, a second subpixel SP2 which realizes a second emission area, and a third subpixel SP3 which realizes a third emission area.

The first subpixel SP1 may realize a first color, the second subpixel SP2 may realize a second color, and the third subpixel SP3 may realize a third color. The first color, the second color, and the third color may each be selected from red, green, and blue such that they do not overlap each other. The subpixels may further include a fourth subpixel which realizes white, but embodiments of the present specification are not necessarily limited to this case.

The second pixel group PXG2 may include a plurality of pixels disposed on the first pixel group PXG1. The second pixel group PXG2 may include a fifth pixel PX5 and a sixth pixel PX6 sequentially arranged along the first direction (e.g., the X-axis direction). The second pixel group PXG2 may be disposed in substantially the same layer as the optical lens unit 230. For example, the optical lens unit 230 may be disposed between a plurality of pixels.

The optical lens unit 230 may include a plurality of lenses 231. For example, the optical lens unit 230 may include a first lens disposed between the fifth pixel PX5 and the sixth pixel PX6 and a second lens formed on a side of the sixth pixel PX6.

In the display device according to the first embodiment of the present specification, the second pixel group PXG2 may be included in a transparent display panel. Therefore, the fifth pixel PX5 and the sixth pixel PX6 may be formed on a transparent substrate TSUB, and a thin-film transistor layer including wiring for driving the second pixel group PXG2 may include a transparent conductive material (TCO) that can transmit light, such as ITO or IZO. For example, the transmittance of the wiring disposed in the thin-film transistor layer which includes the wiring for driving the second pixel group PXG2 may be higher than the transmittance of wiring disposed in a thin-film transistor layer which includes the wiring for driving the first pixel group PXG1. The transparent substrate TSUB may include the same material as a first base substrate 210.

Since the second pixel group PXG2 is disposed between the lenses 231, the fifth pixel PX5 in the second pixel group PXG2 may overlap the first pixel PX1 in the thickness direction of the lenses 231. The sixth pixel PX6 may overlap the third pixel PX3 in the thickness direction of the lenses 231. The second pixel PX2 and the fourth pixel PX4 may overlap the lenses 231 in the thickness direction.

A display device according to an embodiment of the present specification may increase the resolution of a 3D image realized from the display device by increasing the number of pixels overlapping a lens 231 per unit area of the lens 231.

Referring to the first type of light field display or the second type of light field display which realizes a 3D image, a user may inevitably feel a resolution lower than the resolution originally realized in the display panel because viewing angles are mapped. Since an upper part of the display panel is implemented only with the lenses 231, it is difficult to arbitrarily change the area occupied by each lens 231.

According to an embodiment of the present specification, when a 3D image is realized, not only light emitted from a pixel (e.g., the second pixel PX2 or the fourth pixel PX4) overlapping a lens 231 but also light emitted from a pixel (e.g., the first pixel PX1 or the third pixel PX3) not overlapping the lens 231 may travel to the lens 231, as will be described later. Since the amount and/or intensity of light passing through one lens 231 increases, the resolution of a 3D image realized through the lens 231 may relatively increase.

When only a plurality of lenses 231 are placed on the first pixel group PXG1, if the area occupied by each lens 231 is arbitrarily reduced, the number of lenses 231 may increase. When the number of lenses 231 increases, the number of pixels overlapping a lens 231 per unit area of the lens 231 decreases, and the number of pixels that must consider viewing angle mapping increases. As a result, aberration problems, etc. may occur.

Hence, embodiments of the present specification place the second pixel group PXG2 between the lenses 231 and place a plurality of pixels included in the second pixel group PXG2 on the transparent substrate TSUB while reducing the area of each lens 231. In the first embodiment, light passing through the lenses 231 and a filler layer 240 may be always refracted. In a non-switchable display in which only a 3D image is realized, it is difficult to realize a 2D image because light is always refracted. However, in an embodiment, when a 2D image is realized even if the optical lens unit 230 which always refracts light is formed, light emitted from the second pixel group PXG2 may be used. For example, according to the embodiment, there is an advantage in that a 2D image can be realized using light emitted from the second pixel group PXG2 disposed above the first pixel group PXG1 without the need to additionally place driving electrodes, etc.

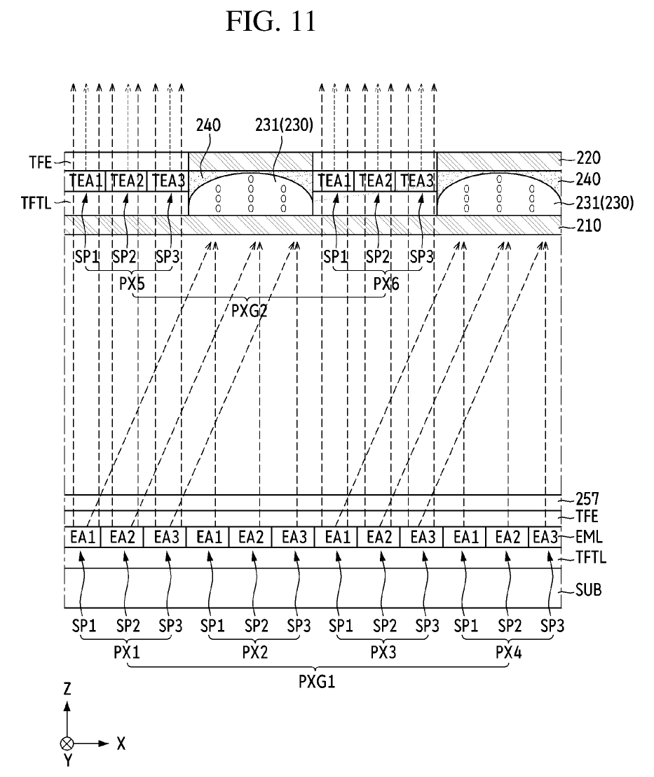

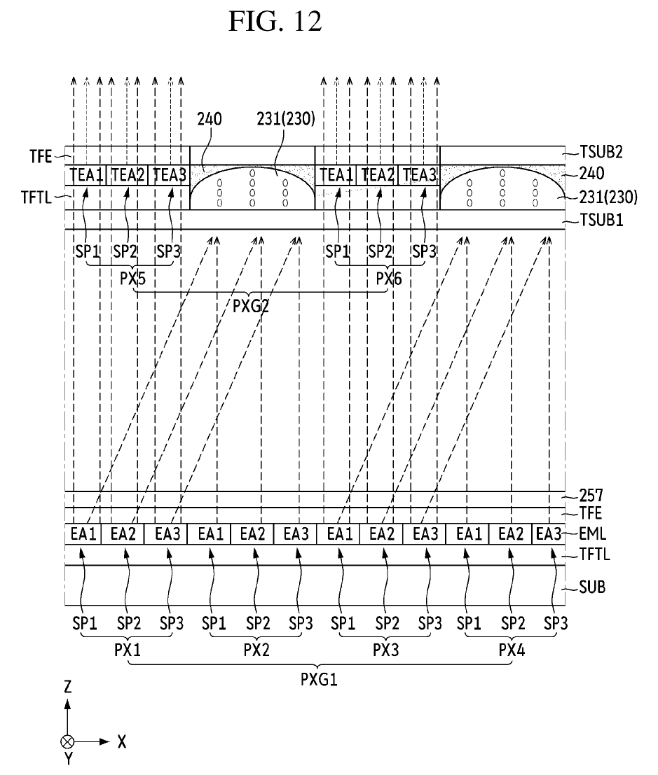

FIG. 11 is a first modification of FIG. 9. FIG. 12 is a second modification of FIG. 9.

Referring to FIG. 11, a second pixel group PXG2 may be formed on a first base substrate 210. The second pixel group PXG2 and an optical lens unit 230 may be alternately arranged on the first base substrate 210. Since both the second pixel group PXG2 and the optical lens unit 230 are formed on one substrate, a manufacturing process can be simplified.

Referring to FIG. 12, an optical lens unit 230 may be formed between transparent substrates TSUB. In this case, a second pixel group PXG2 and the optical lens unit 230 may be formed on a first transparent substrate TSUB1, and the optical lens unit 230 may be disposed between the first transparent substrate TSUB1 and a second transparent substrate TSUB2. Since both the second pixel group PXG2 and the optical lens unit 230 are formed on one substrate, a manufacturing process can be simplified.

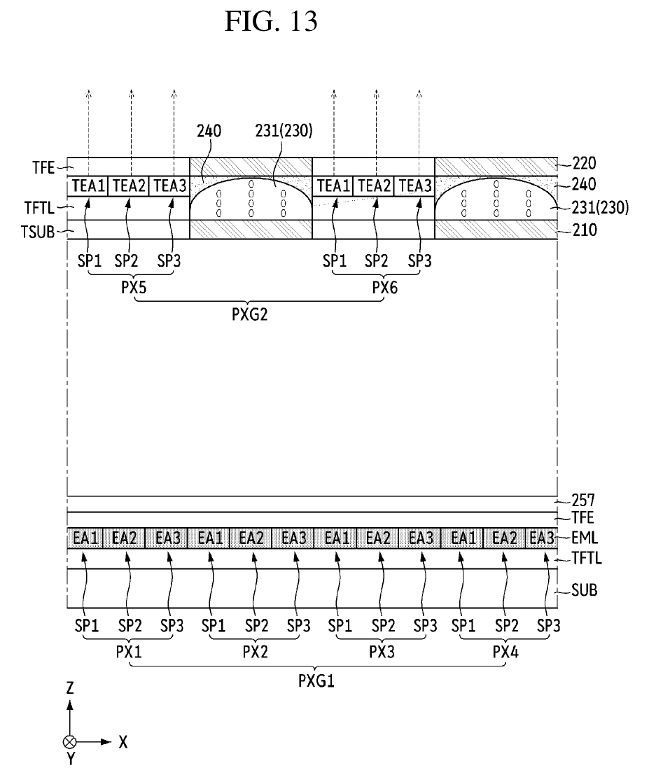

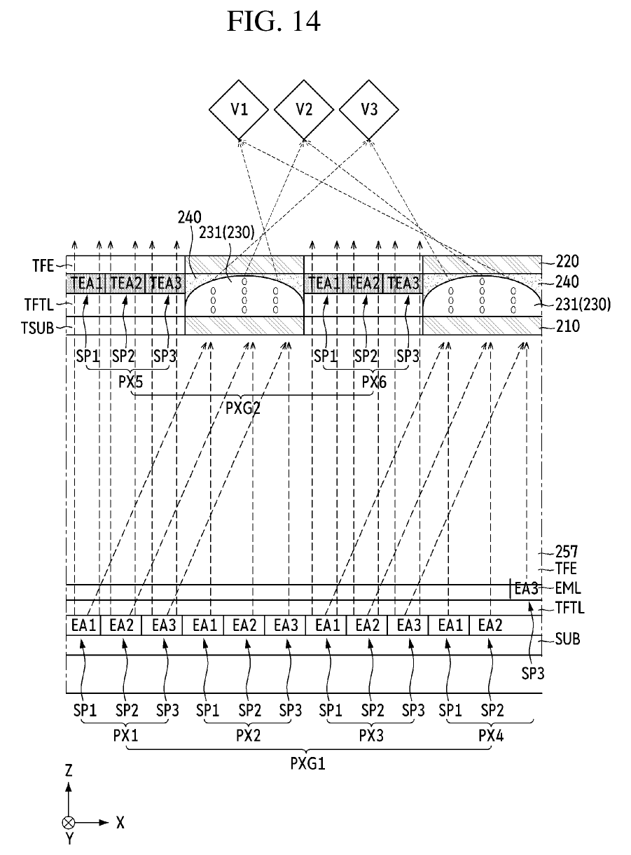

FIG. 13 is a cross-sectional view of the display device according to the first embodiment in which a 2D image is realized. FIG. 14 is a cross-sectional view of the display device according to the first embodiment in which a 3D image is realized.

Referring to FIGS. 13 and 14, when a 2D image is realized, light may be emitted from the second pixel group PXG2. When a 3D image is realized, light may be emitted from the first pixel group PXG1.

When a 2D image is realized, the resolution of the display device may be determined by the second pixel group PXG2. When a 3D image is realized, the resolution of the display device may be determined by the first pixel group PXG1.

In an embodiment, even when a 2D image is realized, light may be emitted from the first pixel group PXG1. However, since light emitted from the first pixel group PXG1 must always be refracted in the display device according to the first embodiment, a data processing process may be required to enable a user to perceive a 2D image. For example, even when light is emitted from the first pixel group PXG1, it is refracted through the lenses 231. Therefore, the light is perceived by both eyes of a user according to viewing angle mapping. A 2D image must present same images to both eyes of the user.

In the first embodiment in which light is emitted from the first pixel group PXG1, different data voltage values may be input when a 2D image is realized and when a 3D image is realized.

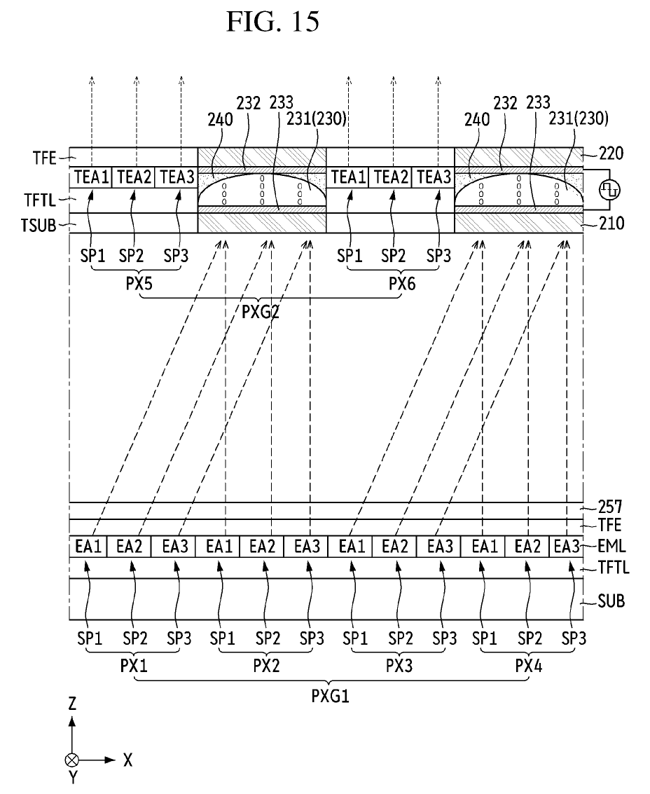

FIG. 15 is a cross-sectional view of a display device according to a second embodiment of the present specification.

Referring to FIG. 15, the display device according to the second embodiment may be a combination of the first type of light field display described above and the display device according to the first embodiment. Therefore, the display device according to the second embodiment may be implemented as a switchable display.

In the switchable display, the refraction of light emitted from a first pixel group PXG1 may be controlled as described above. Accordingly, whether a 2D image or a 3D image is to be realized is determined.

The display device according to the second embodiment is intended to complement the display device according to the first embodiment, which cannot help but rely only on the resolution of a second pixel group PXG2 when realizing a 2D image. Light emitted from the first pixel group PXG1 passes through lenses 231, but might not be refracted because driving electrodes 232 and 233 are arranged.

In the display device according to the second embodiment, when a 2D image is realized, not only light from the second pixel group PXG2 but also light from the first pixel group PXG1 are utilized to realize the image. Therefore, the resolution of the 2D image can be improved. When a 3D image is to be realized, light is emitted from the first pixel group PXG1 as in the first embodiment.

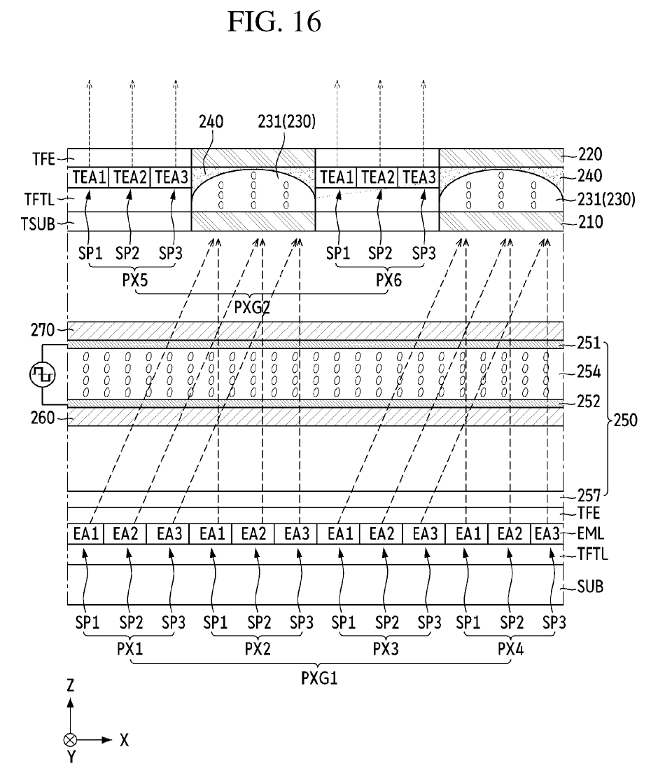

FIG. 16 is a cross-sectional view of a display device according to a third embodiment of the present specification.

Referring to FIG. 16, the display device, according to the third embodiment, may be a combination of the second type of light field display described above and the display device according to the first embodiment. Therefore, the display device according to the third embodiment may be implemented as a switchable display.

The display device according to the third embodiment is intended to complement the display device according to the first embodiment, which cannot help but rely only on the resolution of a second pixel group PXG2 when realizing a 2D image. Light emitted from a first pixel group PXG1 passes through lenses 231, but might not be refracted because driving electrodes 251 and 252 are arranged.

In the display device according to the third embodiment, when a 2D image is realized, not only light from the second pixel group PXG2 but also light from the first pixel group PXG1 are utilized to realize the image. Therefore, the resolution of the 2D image can be improved. When a 3D image is to be realized, light is emitted from the first pixel group PXG1 as in the first embodiment.

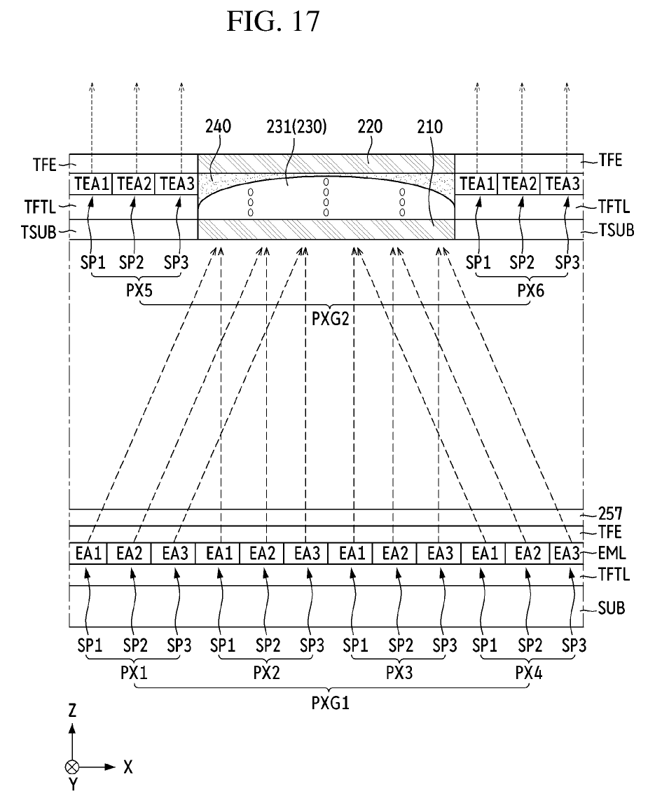

FIG. 17 is a cross-sectional view of a display device according to a fourth embodiment of the present specification.

Referring to FIG. 17, the display device, according to the fourth embodiment, shows that the number of pixels of a first pixel group PXG1 which overlap a lens 231 can be changed. As described above, when the area of the lens 231 is reduced, problems such as aberration and increased refractive index may occur. The fourth embodiment can solve these problems by increasing the number of pixels of the first pixel group PXG1 which overlap the lens 231.

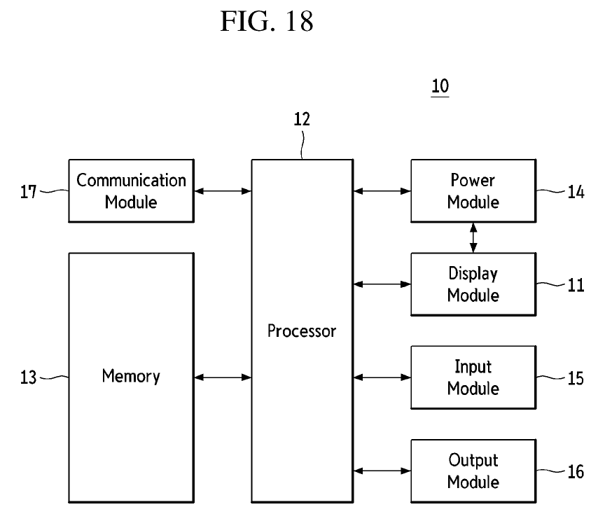

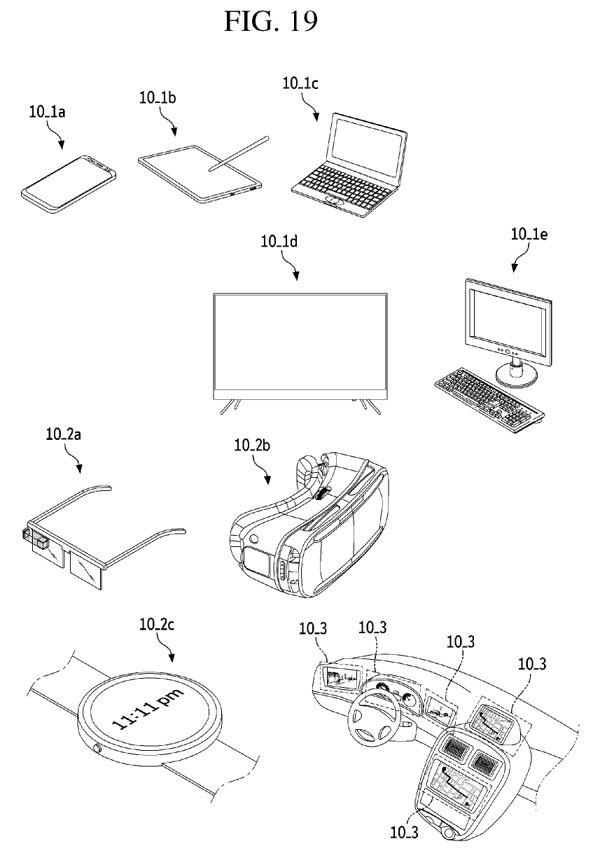

FIG. 18 is a block diagram of an electronic device according to an embodiment of the present specification. FIG. 19 is a schematic diagram of electronic devices according to various embodiments of the present specification.

Referring to FIG. 18, an electronic device 10, according to an embodiment, may include a display module 11, a processor 12, a memory 13, and a power module 14. The display module 11 may be the same as the display module 100 according to FIG. 1 described above.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power necessary for the operation of the electronic device 10 by converting power supplied by the power supply module.

At least one of the elements of the electronic device 10 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

Referring to FIG. 19, various electronic devices to which a display device according to embodiments of the present specification is applied may include image display electronic devices such as a smartphone 10_1a, a tablet computer 10_1b, a laptop/notebook computer 10_1c, a television 10_1d, and a computer monitor 10_1e. In addition, the various electronic devices to which the display device according to the embodiments of the present specification is applied may include wearable electronic devices including display modules, such as smart glasses 10_2a, a head-mounted display 10_2band a smart watch 10_2c, and vehicle electronic devices 10_3 including display modules, such as a center information display (CID) and a room mirror display placed on an instrument cluster, a center fascia and a dashboard of a vehicle.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary and are not necessarily intended to be limiting.

What is claimed is:

1. A display device, comprising:
a first pixel group comprising a first pixel, a second pixel, a third pixel and a fourth pixel, in each of which a plurality of emission areas are defined;
a second pixel group comprising a fifth pixel and a sixth pixel, in each of which a plurality of emission areas are defined; and
an optical lens unit comprising a first lens and a second lens,
wherein the second pixel group and the optical lens unit are each disposed on the first pixel group,
wherein the fifth pixel overlaps the first pixel in a thickness direction of the optical lens unit, and
wherein the first lens overlaps the second pixel in the thickness direction.

2. The display device of claim 1, wherein the first pixel, the second pixel, the third pixel, and the fourth pixel are sequentially arranged along a first direction that is different from the thickness direction, and the fifth pixel, the first lens, the sixth pixel and the second lens are sequentially arranged along the first direction.

3. The display device of claim 2, wherein the sixth pixel overlaps the third pixel in the thickness direction, and the second lens overlaps the fourth pixel in the thickness direction.

4. The display device of claim 1, wherein the optical lens unit is disposed on a first base substrate, and the second pixel group is disposed on a transparent substrate.

5. The display device of claim 4, wherein the optical lens unit is disposed between the first base substrate and a second base substrate, on the first base substrate.

6. The display device of claim 5, further comprising a filler layer disposed between the first base substrate and the second base substrate.

7. The display device of claim 4, wherein the first base substrate comprises a same material as the transparent substrate.

8. The display device of claim 1, wherein light transmittance of wiring for driving the second pixel group is greater than light transmittance of wiring for driving the first pixel group.

9. The display device of claim 1, wherein the first pixel group is configured to emit light when a three-dimensional (3D) image is realized, and the second pixel group is configured to emit light when a two-dimensional (2D) image is realized.

10. The display device of claim 1, further comprising a polarization control unit disposed between the first pixel group and the optical lens unit.

11. The display device of claim 10, wherein the polarization control unit comprises a third base substrate, a fourth base substrate disposed on the third base substrate, and a driving liquid crystal disposed between the third base substrate and the fourth base substrate.

12. The display device of claim 10, wherein the first pixel group is configured to emit light when a 2D image and a 3D image are realized, and the second pixel group is configured to emit light when a 2D image is realized.

13. The display device of claim 11, wherein the polarization control unit further comprises a first driving electrode disposed between the driving liquid crystal and the fourth base substrate and a second driving electrode disposed between the driving liquid crystal and the third base substrate.

14. The display device of claim 1, further comprising a fourth driving electrode and a third driving electrode each disposed on the fourth driving electrode, wherein the optical lens unit is disposed between the fourth driving electrode and the third driving electrode.

15. The display device of claim 14, wherein the first pixel group is configured to emit light when a 2D image and a 3D image are realized, and the second pixel group is configured to emit light when a 2D image is realized.

16. An electronic device, comprising:
a processor configured to provide an image signal;
a display module configured to receive the image signal from the processor and display an image therefrom; and
a power module configured to supply power to the display module,
wherein the display module comprises:
a first pixel group comprising a first pixel, a second pixel, a third pixel, and a fourth pixel in each of which a plurality of emission areas are defined;
a second pixel group comprising a fifth pixel and a sixth pixel in each of which a plurality of emission areas are defined; and
an optical lens unit comprising a first lens and a second lens,
wherein the second pixel group and the optical lens unit are each disposed on the first pixel group,
wherein the fifth pixel overlaps the first pixel in a thickness direction of the optical lens unit, and
wherein the first lens overlaps the second pixel in the thickness direction.

17. The electronic device of claim 16, wherein the optical lens unit is disposed on a first base substrate, and the second pixel group is disposed on a transparent substrate.

18. The electronic device of claim 16, wherein light transmittance of wiring for driving the second pixel group is greater than light transmittance of wiring for driving the first pixel group.

19. The electronic device of claim 16, wherein the first pixel group is configured to emit light when a 3D image is realized, and the second pixel group is configured to emit light when a 2D image is realized.

20. The electronic device of claim 16, further comprising a polarization control unit disposed between the first pixel group and the optical lens unit.
